(19) United States
(12) Patent Application Publication
(10) Pub. No.: US 2009/0139979 A1
(43) Pub. Date: Jun. 4, 2009

(54) PLACING TABLE STRUCTURE, METHOD FOR MANUFACTURING PLACING TABLE STRUCTURE AND HEAT TREATMENT APPARATUS

(75) Inventor: Tomohito Komatsu, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/064,160

(22) PCT Filed: Aug. 10, 2006
(86) PCT No.: PCT/JP2006/315841

§ 371 Date: Feb. 19, 2008

(30) Foreign Application Priority Data
Aug. 19, 2005 (JP) 2005-239207

(51) Int. Cl. H05B 3/68; H01L 21/67; B05D 3/02; B05D 5/00

(52) U.S. Cl. 219/444.1; 219/544; 427/126.2; 427/383.5

(57) ABSTRACT

A mounting table structure capable of preventing cracks in a mounting table made of a ceramic material or at a joint portion between the mounting table and a column for supporting the mounting table. The mounting table structure includes a ceramic mounting table made of a ceramic material for mounting thereon a target object in order to perform a specific heat treatment on the target object in a processing chamber, and a supporting unit for supporting the mounting table. A quartz glass coating layer is formed on a surface of the mounting table while maintaining a compressive stress in a plane direction. As a result, cracks are prevented from occurring in a mounting table made of a ceramic material or at a joint portion between the mounting table and a column for supporting the mounting table.

### FIELD OF THE INVENTION

The present invention relates to a heat treating apparatus of a target object, e.g., a semiconductor wafer or the like, a mounting table structure and a method for manufacturing the mounting table structure.

### BACKGROUND OF THE INVENTION

In general, in order to manufacture a required semiconductor integrated circuit, a target object such as a semiconductor wafer or the like is repeatedly subjected to various processes such as a film forming process, an etching process, a heat treatment, a reforming process, a crystallization process and the like. When those various processes are performed, a processing chamber is supplied with processing gases required for corresponding processes, e.g., a film forming gas for the film forming process, an ozone gas for the reforming process, O₂ gas or a nonreactive gas such as N₂ gas for the crystallization process.

For example, in case of a single-wafer heat treating apparatus for performing a heat treatment on semiconductor wafers one by one, a mounting table having therein a resistance heater is installed in an evacuable processing chamber and, then, a specific processing gas is made to flow while a semiconductor wafer is mounted on the top surface of the mounting table, to thereby perform various heat treatments on the wafer under specific processing conditions.

The mounting table is generally installed with its surface exposed in the processing chamber. Accordingly, a material of the mounting table, e.g., a metal material such as an aluminum alloy, causes a contamination such as a metal contamination due to a small amount of heavy metal or the like contained therein being diffused by heat. In order to suppress the contamination and the like, there has been recently proposed a technique of forming the mounting table itself with a ceramic material (see, Japanese Patent Laid-open Application Nos. H6-252055, 2001-250858 and 2003-289024).

The mounting table made of a ceramic material generally has a resistance heater buried in its top surface side, and is supported by a column made of the ceramic material connected with the backside of the mounting table in the processing chamber.

The mounting table made of a ceramic material can suppress the contamination such as a metal contamination or the like relatively better than a mounting table made of an aluminum alloy.

However, the ceramic material itself is a relatively brittle material, so that the mounting table made of the ceramic material may be easily broken by a thermal stress repetitively applied thereto due to, e.g., repetitive increases/decreases in temperature.

Especially, the ceramic mounting table has a drawback in which cracks occur at a joint portion between the top end of the ceramic column and the bottom surface of the mounting table.

In order to avoid the cracks, a ceramic supporting member for supporting a mounting table is formed in a complex shape, as disclosed in Japanese Patent Laid open Application No. 2001-250858. Otherwise, the joint portion between the mounting table and the supporting member is formed to have a specific curvature radius at the outer periphery thereof, as disclosed in Japanese Patent Laid-open Application No. 2003-289024. However, these are not sufficient to suppress the cracks in the mounting table or the like.

### SUMMARY OF THE INVENTION

The present invention has been conceived to effectively solve the aforementioned drawbacks. It is, therefore, an object of the present invention to provide a mounting table structure capable of preventing cracks in a mounting table made of a ceramic material or at a joint portion between the mounting table and a column for supporting the mounting table, a method for manufacturing the mounting table structure and a heat treating apparatus.

The present inventors have studied on cracks of a ceramic mounting table, and have found that, in manufacturing the ceramic mounting table, it is unavoidable that micro-scratches are generated on a surface of the ceramic mounting table when polishing a surface to be exposed and then machining a joint portion between the mounting table and the column to have a curved surface with a curvature radius R. The present invention has been conceived from the conclusion that the scratches cause cracks especially when a tensile force is applied in a direction perpendicular to the scratches.

In accordance with one aspect of the invention, there is provided a mounting table structure including: a ceramic mounting table made of a ceramic material for mounting thereon a target object in order to perform a specific heat treatment on the target object in a processing chamber; and a supporting unit for supporting the mounting table, wherein a quartz glass coating layer is formed on a surface of the mounting table while maintaining a compressive stress in a plane direction.

Since the quartz glass coating layer is formed on the surface of the mounting table while maintaining a compressive stress in a plane direction, even if scratches or the like are generated on a surface of the quartz glass coating layer, they do not cause cracks in the mounting table due to the compressive stress applied to the quartz glass coating layer.

Further, the quartz glass coating layer itself has a high corrosion resistance to various gases and, thus, the ceramic mounting table are not directly exposed to the gases, which increases durability of the mounting table itself.

In this case, the supporting unit may be a column made of a ceramic material installed upright on a bottom portion of the processing chamber, and wherein the quartz glass coating layer may be formed on a joint portion between a top end of the column and the mounting table and on a portion including at least the top end portion of the column.

Since the quartz glass coating layer is formed on the joint portion between the top end portion of the column and the mounting table and on the portion including at least the top end portion of the column, even if scratches or the like are generated on a surface of the quartz glass coating layer formed on the joint portion, they do not cause cracks in the mounting table due to the compressive stress applied to the quartz glass coating layer.

For example, the mounting table may have a heating unit buried therein to heat the target object.

Further, for example, the quartz glass coating layer may be formed by adhering fused quartz glass at a temperature higher than or equal to a softening point thereof to a surface to be coated with the quartz glass coating layer and then cooling the fused quartz glass to a temperature lower than or equal to a strain point thereof.

Moreover, for example, the ceramic material may have a greater linear expansion coefficient than that of the quartz glass coating layer.

Furthermore, the ceramic material may be selected from the group consisting of aluminum nitride, alumina and silicon carbide.

In accordance with another aspect of the invention, there is provided a method for forming a mounting table structure including a mounting table made of a ceramic material for mounting thereon a target object in order to perform a specific heat treatment on the target object in a processing chamber; and a supporting unit for supporting the mounting table, the method including the steps of: adhering fused quartz glass at a temperature higher than or equal to a softening point thereof to a surface of the mounting table; and forming a quartz glass coating layer while maintaining a compressive stress in a plane direction by cooling the fused quartz glass to a temperature below a strain point thereof.

In this case, after the adhesion step, there may be executed, a step of increasing a temperature of the fused quartz glass to a level higher than or equal to a flow temperature.

For example, the supporting unit may be a column made of a ceramic material and installed upright on a bottom portion of the processing chamber, and wherein the quartz glass coating layer is formed on a joint portion between a top end portion of the column and the mounting table and on a portion including at least the top end portion of the column.

In addition, for example, the ceramic material has a greater linear expansion coefficient than that of the quartz glass coating layer.

In accordance with still another aspect of the invention, there may be provided a heat treating apparatus including: an evacuable processing chamber; a gas supply unit for supplying a specific processing gas into the processing chamber; and the above-described mounting table structure.

In accordance with the mounting table structure, the method for manufacturing the mounting table structure and the heat treating apparatus of the present invention, following effects can be accomplished.

In accordance with the present invention, since the quartz glass coating layer is formed on the surface of the mounting table while maintaining a compressive stress in a plane direction, even if scratches or the like are generated on a surface of the quartz glass coating layer, they do not cause cracks in the mounting table due to the compressive stress applied to the quartz glass coating layer.

Further, the quartz glass coating layer itself has a high corrosion resistance to various gases and the ceramic mounting table are not directly exposed to the gases, which increases durability of the mounting table itself.

Furthermore, since the quartz glass coating layer is formed on the joint portion between the top end portion of the column and the mounting table and on the portion including at least the top end portion of the column, even if scratches or the like are generated on a surface of the quartz glass coating layer formed on the joint portion, they do not cause cracks in the mounting table due to the compressive stress applied to the quartz glass coating layer.

### BRIEF DESCRIPTION OF THE DRAWINGS

FIG. 1 is a cross sectional view showing a configuration of a heat treating apparatus in accordance with the present invention;

FIGS. 2A to 2F provide flow charts for describing principal processes for coating a quartz glass coating layer on a surface of a ceramic member with a compressive stress applied thereto;

FIG. 3 presents a graph depicting temperature dependency of viscosities of various quartz glasses (quoted from “World of Quartz Glass” Nobu Kuzuu, ISBN 4-7693-4100-8);

FIG. 4 represents a graph showing temperature dependency of linear expansion coefficients of various quartz glasses (quoted from “World of Quartz Glass” Nobu Kuzuu, ISBN 4-7693-4100-8); and

FIG. 5 offers a diagram illustrating a modified example of the heat treating apparatus of the present invention.

### DETAILED DESCRIPTION OF THE EMBODIMENTS

Hereinafter, a mounting table structure, a method for manufacturing the mounting table structure and a heat treating apparatus in accordance with embodiments of the present invention will be described with reference to the accompanying drawings.

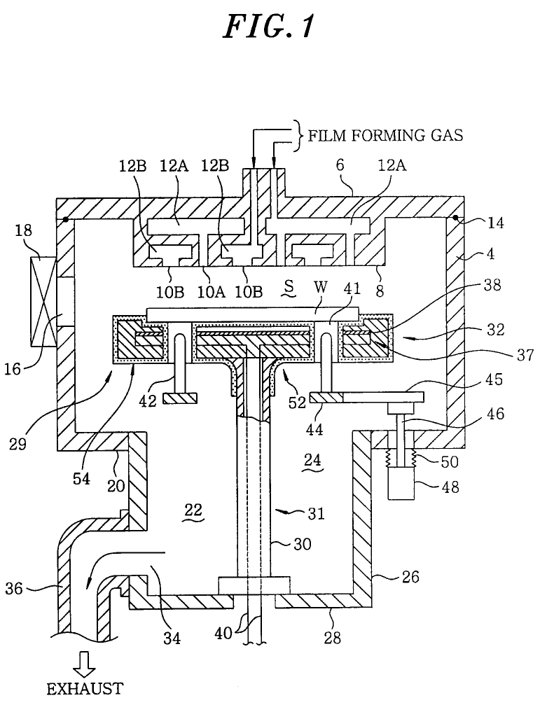

FIG. 1 is a cross sectional view showing a configuration of the heat treating apparatus in accordance with an embodiment of the present invention.

As illustrated, the heat treating apparatus 2 has a processing chamber 4 made of aluminum and having a substantially circular inner cross section. Provided on a ceiling portion of the processing chamber 4 is a shower head 6 serving as a gas supply unit for supplying a required processing gas, e.g., a film forming gas. The processing gas is injected into a processing space S through a plurality of gas injection openings formed in a gas injection surface 8 corresponding to a bottom surface of the shower head 6.

The shower head 6 has therein two partitioned hollow gas diffusion chambers 12A and 12B. The processing gas is introduced into the gas diffusion chambers 12A and 12B, diffused in a horizontal direction and then injected through the gas injection openings 10A and 10B respectively communicating with the gas diffusion chambers 12A and 12B. The entire body of the shower head 6 is made of, e.g., nickel, a nickel alloy such as Hastelloy (registered trademark), aluminum or an aluminum alloy. Alternatively, the shower head 6 may have a single gas diffusion chamber. Further, a seal member 14 such as an O-rings or the like is interposed at a joint portion between the shower head 6 and the top opening of the processing chamber 4, to thereby maintain airtightness in the processing chamber 4.

Provided on a sidewall of the processing chamber 4 is a loading/unloading port 16 for loading/unloading a semiconductor wafer W as a target object into/from the processing chamber 4. The loading/unloading port 16 is provided with a gate valve 18 that can be opened and closed airtightly.

In addition, an exhaust gas downdraft space 22 is formed at a bottom portion 20 of the processing chamber 4. To be specific, a large opening 24 is formed at a central portion of the chamber bottom portion 20. A cylindrical wall 26 having a bottom portion is connected to the opening 24 and extends downward therefrom, to thereby form the exhaust gas downdraft space 22. Further, a mounting table structure 29 of the present invention is disposed upright on a bottom portion 28 of the cylindrical wall 26 which defines the exhaust gas downdraft space 22. Specifically, the mounting table structure 29 includes a cylindrical column 30 serving as a supporting unit 31 and a mounting table 32 fixedly joined to a top end portion of the column 30, the column 30 and the mounting table 32 being made of a same material, e.g., ceramic. The mounting table structure 29 will be described in detail later.

The entrance opening 24 of the exhaust gas downdraft space 22 is formed to have a diameter smaller than that of the mounting table 32. The processing gas flows downward from an outer peripheral portion of the mounting table 32 and is then introduced into the opening 24 via a lower portion of the mounting table 32. Formed on a lower sidewall of the cylindrical wall 26 is a gas exhaust port 34 facing the exhaust gas downdraft space 22. The gas exhaust port 34 is connected with a gas exhaust line 36 in which a vacuum pump (not shown) is installed, so that atmosphere in the processing chamber 4 and the exhaust gas downdraft space 22 can be vacuum exhausted.

Moreover, installed in the middle of the gas exhaust line 36 is a pressure control valve (not shown) whose opening degree is controllable. By automatically controlling the valve opening degree, the pressure in the processing chamber 4 can be maintained at a specific level or quickly changed to a required level.

Besides, a resistance heater 38, e.g., a carbon heater, serving as a heating unit 37 is buried in a specific pattern in the mounting table 32. The semiconductor wafer W as a target object can be mounted on the top surface of the mounting table 32. Since the resistance heater 38 is connected with power supply lines 40 arranged inside the cylindrical column 30 serving as the supporting unit 31, the power can be supplied while being controlled. Further, the resistance hater 38 is divided into an inner section positioned at a central portion of the mounting table 32 and an outer section coaxially surrounding the inner section and it is possible to individually control the powers for the sections. Although only two power supply lines 40 are illustrated in the drawing, there are actually provided four power supply lines 40. Further, the column 30 may be provided in plural.

A plurality of, e.g., three, pin holes 41 are vertically formed in the mounting table 32 (only two of them are illustrated in FIG. 1). Further, upthrust pins 42 are inserted in the respective pin holes 41 to be able to move up and down therethrough. Moreover, a circular ring shaped upthrust ring 44 made of a ceramic material, e.g., alumina, are provided under the upthrust pins 42 and the lower ends of the upthrust pins 42 are placed on the upthrust ring 44. An arm unit 45 extending from the upthrust ring 44 is connected with an up/down rod 46 penetrating the chamber bottom portion 20 and the up/down rod 46 is vertically movable by an actuator 48. Accordingly, the upthrust pins 42 can be protruded upward from the pin holes 41 when transferring the wafer W. Furthermore, an expansible/contractible bellows 50 is installed where the up/down rod 46 of the actuator 48 penetrates the chamber bottom portion, so that the up/down rod 46 can move vertically while maintaining the airtightness in the processing chamber 4.

The following is a detailed description of the mounting table structure 29 of the present invention. As described above, the mounting table 32 and the column 30 are made of a ceramic material. As for the ceramic material, there can be used, e.g., aluminum nitride (AlN). A thickness of the mounting table 32 is set to be about 20 mm. Further, the top end portion of the column 30 is joined to a substantially central portion of the bottom surface of the disc-shaped mounting table 32. A joint portion 52 is formed to have a curved surface with a curvature radius R, to thereby suppress the generation of cracks.

Moreover, a quartz glass coating layer 54 is formed on the surface of the mounting table 32, the joint portion 52 between the mounting table 32 and the column 30 and the surface of a portion of the column 30 including at least the top end portion thereof while maintaining a compressive stress applied thereto in a plane direction. To be specific, the quartz glass coating layer 54 is formed to cover the entire surface of the mounting table 32, i.e., the top surface, the side surface and the bottom surface thereof. Besides, the quartz glass coating layer 54 is formed to cover inner peripheral surfaces of the pin holes 41 of the mounting table 32.

With respect to the column 30, the quartz glass coating layer 54 is integrally formed to cover the curved surface of the joint portion 52 of the mounting table 32 and the entire surface of the top end portion of the column 30. Further, a stress of tensile direction (tensile stress) remains in the ceramic material coated with the quartz glass coating layer 54. Furthermore, as for the column 30, the quartz glass coating layer 54 may be formed on the entire surface of the column 30, in addition to the top end portion thereof.

The quartz glass coating layer 54 is formed to have a thickness of about 0.01 mm or greater, e.g., about 0.5 mm. Cracks are prevented from occurring in the mounting table 32 itself or in the joint portion 52 of the column 30, by forming the quartz glass coating layer 54 thereon while maintaining a compressive stress applied thereto in a plane direction as described above. When the quartz glass coating layer 54 is formed to have a thickness smaller than about 0.01 mm, the effects derived from the presence of the quartz glass coating layer 54 are not fully obtained. In that case, by using the mounting table 32 and the column 30 having a linear expansion coefficient greater than that of the quartz glass coating layer 54, the compressive stress can be maintained (remain) in the quartz glass coating layer 54, as will be described later.

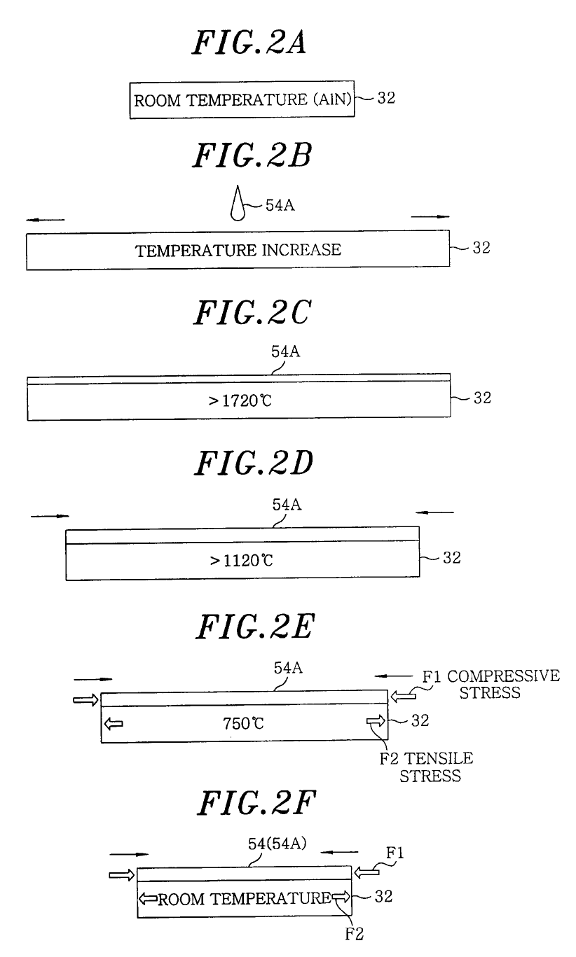

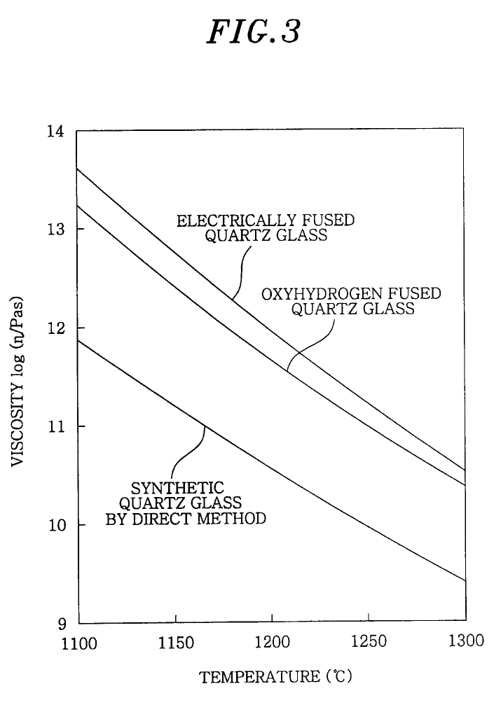

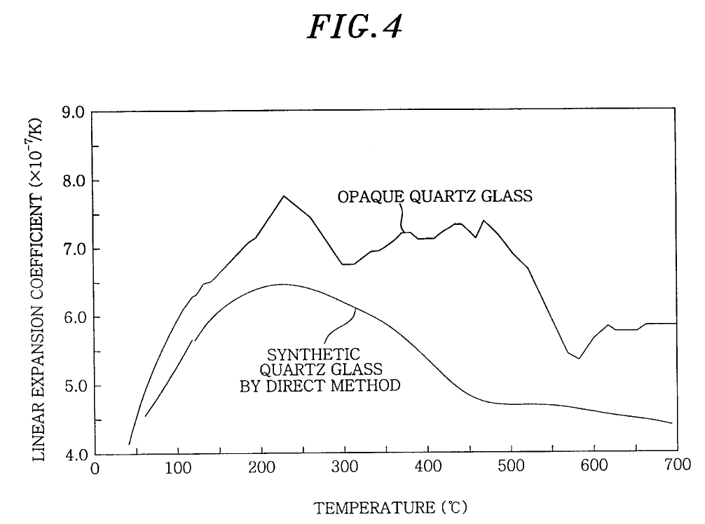

Hereinafter, a method for forming the quartz glass coating layer 54 will be described. FIGS. 2A to 2F provide flow charts of principal processes for coating the quartz glass coating layer 54 on a surface of a ceramic member while a compressive stress remains; FIG. 3 presents a graph depicting temperature dependency of viscosities of various quartz glasses; and FIG. 4 represents a graph showing temperature dependency of linear expansion coefficients of various quartz glasses. As described above, a central portion of the bottom surface of the mounting table 32 made of aluminum nitride as a ceramic material is joined with the column 30 made of the aluminum nitride. Then, the surfaces of the mounting member 32 and the column 30 are polished to be flat and the surface of the joint portion 52 is polished to be curved, after which the quartz glass coating layer 54 is formed thereon. FIGS. 2A to 2F show principle for forming the quartz glass coating layer 54 while the compressive stress remains thereon as described above. Herein, there will be described an exemplary case where the quartz glass coating layer 54 is formed only on the top surface of the mounting table 32.

The quartz glass coating layer 54 is formed by utilizing a difference in linear expansion coefficients between the quartz glass coating layer 54 and the ceramic to be coated therewith. To be specific, a ceramic having a linear expansion coefficient greater than that of the quartz glass coating layer 54 is used, and, e.g., aluminum nitride (AlN) is used an example thereof, as described above.

In view of fracture mechanics, a fracture strength of a test specimen having on its surface cracks is reduced by about 60% compared with that of a test specimen having therein the same cracks. This phenomenon is referred to as “skin effect”. For example, a tempered glass has a strength several times greater than that of a conventional glass by utilizing the skin effect. That is, the tempered glass has, as a result of a heat treatment, a residual stress of compressive direction (compressive stress) on its surface and a stress of tensile direction (tensile stress) in its inside. In the present invention, the strength of the mounting table 32 and the like is enhanced by forming the quartz glass coating layer 54 thereon while utilizing the skin effect.

The processes described in FIGS. 2A to 2F are performed, e.g., in the vacuum state. To begin with, the mounting table 32, of a specific length, made of aluminum nitride is provided at a room temperature, as illustrated in FIG. 2A. A sintering temperature of the aluminum nitride is around about 1900° C. Next, as shown in FIG. 2B, a quartz glass 54A is provided on the surface of the mounting table 32 while increasing a temperature of the mounting table 32. As can be seen from FIG. 2C, the mounting table 32 is heated to a temperature greater than or equal to a softening point of the quartz glass 54A, e.g., 1720° C. In this case, it is preferable that the mounting table 32 is heated to a temperature higher than or equal to a flow temperature of the quartz glass 54A, e.g., 1800° C. Accordingly, the quartz glass 54A on the mounting table 32 is fused and has a low viscosity (e.g., about 10⁵ P or less), so that the quartz glass 54A flows in a plane direction to be uniformly adhered to (i.e., coated on) the surface of the mounting table 32.

FIG. 3 depicts temperature dependency of viscosities of various fused quartz glasses (electrically fused quartz glass, oxyhydrogen fused quartz glass and synthetic quartz glass by a direct method). The viscosities of all the glasses deteriorate as the temperature increases.

Moreover, the quartz glass 54A may be provided on the surface of the mounting table 32 after being heated to a temperature higher than or equal to its softening point. In this case, the quartz glass 54A is immediately fused and uniformly diffused in a plane direction.

Next, the mounting table 32 is maintained for specified time, e.g., about 15 minutes, at the temperature higher than or equal to the softening point, as depicted in FIG. 2C. Thereafter, as illustrated in FIGS. 2D to 2F, the mounting table 32 is slowly cooled to a room temperature while controlling the rate of temperature decrease.

Accordingly, the quartz glass 54A that has been uniformly diffused is cooled to be the quartz glass coating layer 54. The rate of temperature decrease is set to a level capable of preventing cracks of the mounting table 32 made of a ceramic material and the quartz glass coating layer 54 coated thereon.

As the mounting table 32 is slowly cooled to a strain point of the fused quartz glass, e.g., 1120° C., the mounting table 32 made of a ceramic material and the fused quartz glass coating layer 54A are thermally contracted together in accordance with the linear expansion coefficients thereof, respectively, without causing an internal stress.

Further, when the mounting table 32 is cooled below the strain point, the mounting table 32 and the quartz glass 54A are further thermally contracted and the viscosity of the quartz glass 54A considerably increases. Thus, the internal stress is not relieved.

Referring to FIG. 2E, there is illustrated a state where the temperature of the mounting table 32 has decreased to about 750° C. When the temperature is below the strain point, the linear expansion coefficient of the quartz glass 54A is about 5.5×10⁻⁷/° C. FIG. 4 presents temperature dependency of linear expansion coefficients (linear expansion rate) of various fused quartz glasses (a synthetic quartz glass by a direct method and an opaque quartz glass). When the temperature ranges from about 350° C. to about 700° C., an average linear expansion coefficient of all the quartz glasses is about 5.5×10⁻⁷/° C. Meanwhile, a linear expansion coefficient of aluminum nitride is about 5.5×10⁻⁶/° C., which is 10 times greater than that of the quartz glass 54A. In other words, the mounting table 32 made of a ceramic material is thermally contracted more than the quartz glass 54A. Therefore, the stress derived from the difference in the linear expansion coefficients between the mounting table 32 and the quartz glass 54A remains as a strain amount. As a consequence, a compressive stress indicated by an arrow F1 is applied to the quartz glass 54A, whereas a tensile stress indicated by an arrow F2 is applied to the mounting table 32 made of a ceramic material.

When the mounting table 32 is cooled to a room temperature, the mounting table 32 and the quartz glass 54A are further thermally contracted. As a result, the compressive stress F1 and the tensile stress F2, both being derived from the difference in the linear expansion coefficients between the mounting table 32 and the quartz glass 54A, remain as residual stresses in the quartz glass coating layer 54 and the mounting table 32. In this way, the compressive stress in the plane direction can be maintained in the quartz glass coating layer 54.

Since the thickness of the quartz glass coating layer 54 is much smaller than that of the mounting table 32 made of a ceramic material, the tensile force F2 remaining in the mounting table 32 is relatively smaller than the compressive stress F1 remaining in the quartz glass coating layer 54, which does not affect the mounting table 32.

The quartz glass coating layer 54 is formed on the surface of the mounting table 32 while maintaining a compressive stress applied thereto in the plane direction. Thus, even if scratches or the like are generated on a surface of the quartz glass coating layer 54, they do not cause cracks in the mounting table 32 due to the compressive stress applied to the quartz glass coating layer 54. Further, the quartz glass coating layer itself has a high corrosion resistance to various gases and the ceramic mounting table are not directly exposed to the gases, which increases durability of the mounting table itself.

Further, since the quartz glass coating layer 54 is formed on the joint portion 52 between the top end portion of the column 30 and the mounting table 32 and on the portion including at least the top end portion of the column 30, even if scratches or the like are generated on a surface of the quartz glass coating layer 54 formed on the joint portion 52, they do not cause cracks in the mounting table itself due to the compressive stress applied to the quartz glass coating layer 54.

Besides, the mounting table 32 is used at a temperature below the strain point of the quartz glass 54A during general processes, so that the residual stresses, i.e., the compressive stress F1 and the tensile stress F2, are not relieved to be lost.

As an additional effect, a main body of the mounting table or a main body of the column, each being made of aluminum nitride, can be protected from a processing gas due to the presence of the quartz glass coating layer 54 coated on the mounting table 32 or on the upper peripheral portion of the column 30. Accordingly, a corrosion resistance to the processing gas is not required for the aluminum nitride itself, which increases the flexibility of the selection of material. For example, the mounting table 32 can be made of aluminum nitride having a low corrosion resistance and a high thermal conductivity.

Further, the quartz glass forming the quartz glass coating layer 54 may be gradually corroded by some processing gases. In this case, residual life of the mounting table 32 can be determined by observing the appearance of the mounting table 32 through the transparent quartz glass coating layer 54.

Further, although the resistance heater 38 buried in the mounting table 32 is used as the heating unit 37 in the embodiment of the above-described heat treating apparatus, a heating lamp may be used as the heating unit 37.

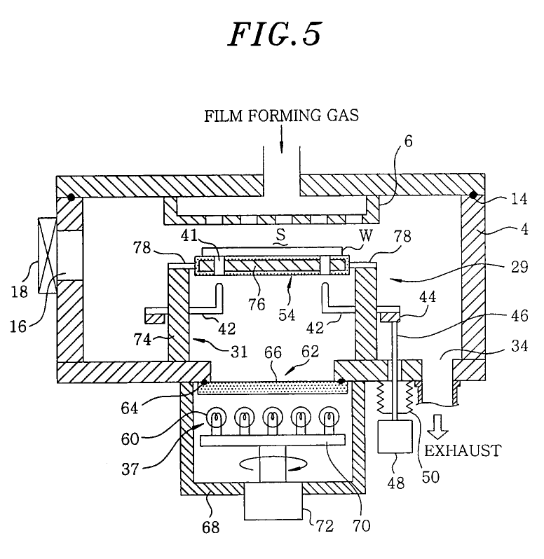

FIG. 5 offers a diagram illustrating such a modified example of the heat treating apparatus of the present invention. In FIG. 5, same parts as those shown in the FIG. 1 are assigned like reference numerals, and redundant descriptions thereof will be omitted. In the modified example shown in FIG. 5, a plurality of heating lamps 60 are provided as the heating unit 37, instead of the resistance heater 38 (see, FIG. 1). To be specific, an opening 62 of a large diameter is formed in the bottom portion 20 of the processing chamber 4 and a transmitting plate 66 made of a transparent quartz plate is provided at the opening 62 via a seal member 64 such as an O-ring or the like.

Further, a lamp housing 68 is disposed under the transmitting plate 66. The heating lamps 60 are installed in the lamp housing 68 while being attached to a rotatable table 70 also serving as a reflecting plate. The rotatable table 70 can be rotated by a rotating motor 72. Accordingly, heat rays from the heating lamps 60 penetrate through the transparent plate 66 to be irradiated on a backside of a mounting table 76, thereby heating the mounting table 76.

In a mounting table structure 29, a cylindrical reflector 74 of a large diameter is disposed, as a supporting unit 31, on the bottom portion of the chamber and the mounting table 76 made of a ceramic material is supported by a plurality of, e.g., three, supporting rods 78 (only two of them are illustrated) horizontally extending from the top of the reflector 74 having an inner surface formed as a reflective surface. Further, as in the aforementioned embodiment, the entire surface of the mounting table 76, i.e., the top surface, the side surface and the bottom surface thereof, are coated with a quartz glass coating layer 54. In this embodiment, black aluminum nitride that does not transmit light is used as a ceramic material forming the mounting table 76. A thickness thereof is set to be very thin, e.g., about 3 mm to 4 mm.

The modified example can also provide the advantageous effects same as those of the aforementioned embodiment. Since the quartz glass coating layer 54 is formed on the surface of the mounting table 76 while maintaining a compressive stress applied thereto in the plane direction, even if scratches or the like are generated on a surface of the quartz glass coating layer 54, they do not cause cracks in the mounting table due to the compressive stress applied to the quartz glass coating layer 54. Further, the quartz glass coating layer itself has a high corrosion resistance to various gases and the ceramic mounting table are not directly exposed to the gases, which increases durability of the mounting table itself.

Although aluminum nitride is exemplified as the ceramic material in the aforementioned embodiment, alumina (Al₂O₃), silicon carbide and the like may be used as the ceramic material.

Moreover, the present invention can be applied to various heat treatments performed on a wafer W, such as a film forming process, an etching process, a reforming process, an annealing process and the like.

Furthermore, a target object of the present invention is not limited to the semiconductor wafer and may also be an LCD substrate, a glass substrate, a ceramic substrate and the like.

1. A mounting table structure comprising:
a mounting table made of a ceramic material for mounting thereon a target object in order to perform a specific heat treatment on the target object in a processing chamber; and
a supporting unit for supporting the mounting table, wherein a quartz glass coating layer is formed on a surface of the mounting table while maintaining a compressive stress in a plane direction.

2. The mounting table structure of claim 1, wherein the supporting unit is a column made of a ceramic material installed upright on a bottom portion of the processing chamber, and wherein the quartz glass coating layer is formed on a joint portion between a top end portion of the column and the mounting table and on a portion including at least the top end portion of the column.

3. The mounting table structure of claim 1, wherein the mounting table has a heating unit buried therein to heat the target object.

4. The mounting table structure of claim 1, wherein the quartz glass coating layer is formed by adhering fused quartz glass at a temperature higher than or equal to a softening point thereof to a surface to be coated with the quartz glass coating layer and then cooling the fused quartz glass to a temperature lower than or equal to a strain point thereof.

5. The mounting table structure of claim 1, wherein the ceramic material has a greater linear expansion coefficient than that of the quartz glass coating layer.

6. The mounting table structure of claim 1, wherein the ceramic material is selected from the group consisting of aluminum nitride, alumina and silicon carbide.

7. A method for forming a mounting table structure including a mounting table made of a ceramic material for mounting thereon a target object in order to perform a specific heat treatment on the target object in a processing chamber; and a supporting unit for supporting the mounting table, the method comprising the steps of:
adhering fused quartz glass at a temperature higher than or equal to a softening point thereof to a surface of the mounting table; and
forming a quartz glass coating layer while maintaining a compressive stress in a plane direction by cooling the fused quartz glass to a temperature below a strain point thereof.

8. The method for manufacturing a mounting table structure of claim 7, further comprising, after the adhesion step, a step of increasing a temperature of the fused quartz glass to a level higher than or equal to a flow temperature.

9. The method for manufacturing a mounting table structure of claim 7, wherein the supporting unit is a column made of a ceramic material and installed upright on a bottom portion of the processing chamber, and wherein the quartz glass coating layer is formed on a joint portion between a top end portion of the column and the mounting table and on a portion including at least the top end portion of the column.

10. The method for manufacturing a mounting table structure of claim 7, wherein the ceramic material has a greater linear expansion coefficient than that of the quartz glass coating layer.

11. A heat treating apparatus comprising:
an evacuable processing chamber;
a gas supply unit for supplying a specific processing gas into the processing chamber; and
the mounting table structure described in claim 1.
